(19) United States
(12) Patent Application Publication
(10) Pub. No.: US 2016/0086880 A1
(43) Pub. Date: Mar. 24, 2016

(54) COPPER WIRE THROUGH SILICON VIA CONNECTION

(71) Applicants: Navas Khan Oratti Kalandar, Austin, TX (US); Wai Yew Lo, Petaling Jaya (MY); Wen Shi Koh, Petaling Jaya (MY)

(72) Inventors: Navas Khan Oratti Kalandar, Austin, TX (US); Wai Yew Lo, Petaling Jaya (MY); Wen Shi Koh, Petaling Jaya (MY)

(73) Assignee: Freescale Semiconductor, Inc., Austin, TX (US)

(21) Appl. No.: 14/493,332

(22) Filed: Sep. 22, 2014

(51) Int. Cl. H01L 23/498; H01L 21/56; H01L 23/31; H01L 21/48; H01L 23/00; H01L 23/29

(52) U.S. Cl. CPC H01L 23/49838; H01L 24/17; H01L 23/49827; H01L 23/293; H01L 23/3178; H01L 21/486; H01L 21/4853; H01L 21/56; H01L 24/81; H01L 2224/0237; H01L 2224/16227

(57) ABSTRACT

A semiconductor device includes a semiconductor substrate having opposing first and second main surfaces, a via (TSV) extending from the first main surface of the substrate to the second main surface of the substrate, first electrical connectors formed near the first main surface and second electrical connectors formed near the second main surface. There are insulated bond wires, each extending through the via and having a first end bonded to a respective one of the first electrical connectors and a second end bonded to a respective one of the second electrical connectors. The via may be filled with an encapsulating material.

### BACKGROUND OF THE INVENTION

The present invention is directed to semiconductor devices and, more particularly, to electrical connections made using through silicon vias.

So-called “2.5D” integrated circuit packages have a silicon interposer for coupling active dies to package substrates. Current methods for fabricating silicon interposers and the overall packages are lengthy and expensive. For example, silicon interposers are typically manufactured having plated vias, requiring silicon etching, plating, chemical mechanical polishing (CMP), and other fabrication steps, which adds to manufacturing time and increases the cost. In addition, the silicon wafer used for the interposer much be relatively thin (e.g., less than 100 μm) to ease the depth of silicon etching and via plating required. On the other hand thought, thinner silicon wafers pose challenges for wafer handling.

It therefore would be desirable to have a method for manufacturing a silicon interposer and an integrated circuit package containing the same that reduces the number of overall fabrication steps and reduces the cost, yet still provides a reliable interconnection for 2.5D or other integrated circuit packages.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale. Notably, certain vertical dimensions have been exaggerated relative to certain horizontal dimensions.

In the drawings:

FIG. 1 is a cross-sectional side elevational view of a semiconductor device in accordance with a preferred embodiment of the present invention;

FIG. 2 is a cross-sectional side elevational view of a semiconductor substrate for use in forming the device of FIG. 1;

FIG. 3 is a cross-sectional side elevational view of the semiconductor substrate of FIG. 2 following the formation of vias;

FIG. 4 is a cross-sectional side elevational view of the semiconductor substrate of FIG. 3 following the attachment of bond wires; and

FIG. 5 is a cross-sectional side elevational view of the semiconductor substrate of FIG. 4 following deposition of encapsulation material.

### DETAILED DESCRIPTION OF THE INVENTION

In one embodiment, the present invention provides a semiconductor device including a semiconductor substrate having opposing first and second main surfaces, a via extending from the first main surface of the semiconductor substrate to the second main surface of the semiconductor substrate, a plurality of first electrical connectors formed proximate the first main surface of the semiconductor substrate and a plurality of second electrical connectors formed proximate the second main surface of the semiconductor substrate, a plurality of insulated bond wires, each extending through the via and having a first end bonded to a respective one of the plurality of first electrical connectors and a second end bonded to a respective one of the plurality of second electrical connectors, and an encapsulating material disposed at least within the via and encapsulating the plurality of insulated bond wires.

In another embodiment, the present invention provides a method of forming a semiconductor device. The method includes providing a semiconductor substrate having opposing first and second main surfaces, forming a plurality of first electrical connectors on the first main surface of the semiconductor substrate and a plurality of second electrical connectors on the second main surface of the semiconductor substrate, forming a via extending from the first main surface of the semiconductor substrate to the second main surface of the semiconductor substrate, wire bonding a first end of each of a plurality of insulated bond wires to a respective one of the plurality of first electrical connectors and a second end of each of the plurality of insulated bond wires to a respective one of the plurality of second electrical connectors such that each of the plurality of bond wires extends through the via, and encapsulating the plurality of bond wires in an encapsulating material. The encapsulating material is disposed at least within the via.

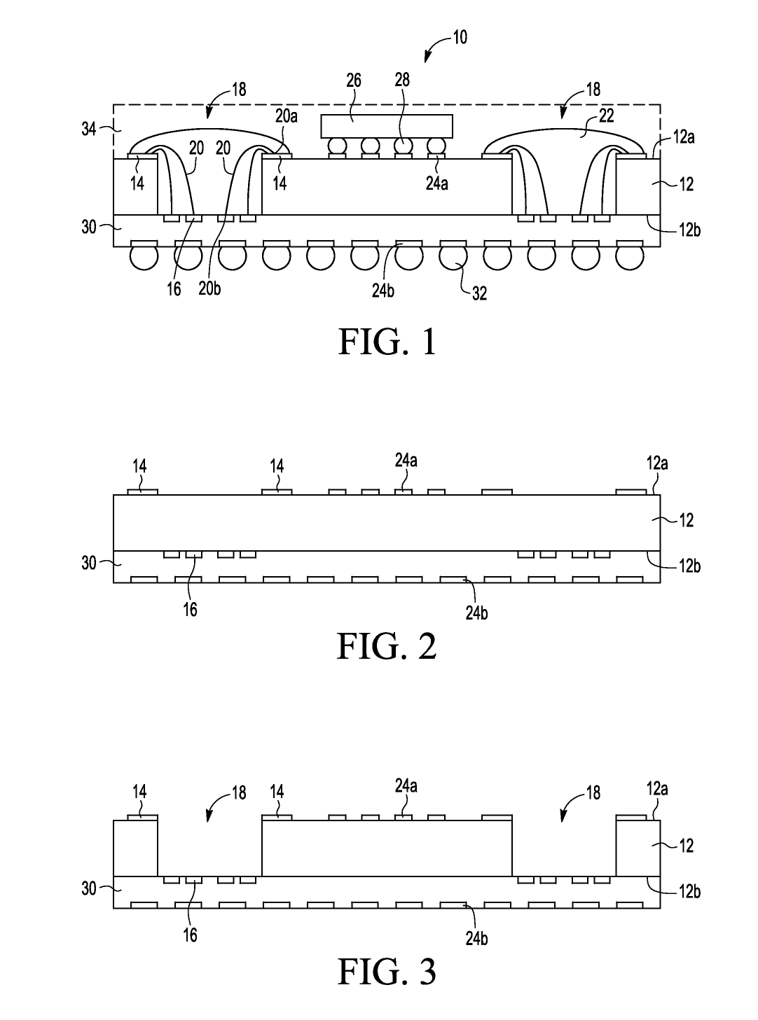

Referring now to the drawings, wherein the same reference numerals are used to designate the same components throughout the several figures, there is shown in FIG. 1 an embodiment of a semiconductor device 10 in accordance with the present invention. The semiconductor device 10 includes a semiconductor substrate 12 having opposing first and second main surfaces 12a, 12b. The semiconductor substrate 12 is preferably formed from silicon (Si), although other semiconductor materials or combinations thereof can be used as well, such as gallium arsenide, silicon germanium, monocrystalline silicon, or the like.

A plurality of first electrical connectors or contacts 14 is formed proximate, and preferably on, the first main surface 12a of the semiconductor substrate 12. The first electrical contacts 14 are preferably in the form of bonding pads, although other types of contacts may also be used. The first electrical contacts 14 may be made from copper (Cu) and/or other conductive materials, and may be coated, alloyed or pre-plated with a metal layer or layers such as gold (Au), nickel (Ni), palladium (PD), tin (Sn) or the like. Although the first electrical contacts 14 are shown in FIG. 1 as extending away from (above) the first main surface 12a of the semiconductor substrate 12, the first electrical contacts 14 may also be co-planar with and/or at least partially embedded into the first main surface 12a of the semiconductor substrate 12.

In one embodiment, after the first electrical contacts 14 (i.e., redistribution traces) are deposited on the first main surface 12a of the substrate 12, the substrate 12 is thinned to about 200 um or other suitable thickness.

A plurality of second electrical connectors or contacts 16 is formed proximate the second main surface 12b of the semiconductor substrate 12. That is, as will be described later, a redistribution layer 30 is formed on the second main surface 12b of the substrate 12.

A via 18 (often referred to as a Through Silicon Via or TSV) is provided through the semiconductor substrate 12 extending from the first main surface 12a to the second main surface 12b thereof. To form the TSV or via 18, the substrate 12 (and RDL 30) may be attached to a support wafer (not shown) using suitable temporary adhesive and then an etching process performed. The via 18 provides a channel for connecting the first electrical contacts 14 with respective ones of the second electrical contacts 16. The connections are facilitated by a plurality of bond wires 20, which preferably comprise insulated or coated bond wires. In one embodiment, the bond wires 20 are preferably an insulated copper wire, gold wire, or the like, as are known in the art. For example, a typical insulated copper bond wire may have a diameter of 18-25 μm, such as insulated PdCu and insulated Cu bond wires available from W. C. Heraeus GmbH of Hanau, Germany. Coated bond wires may also be used, where an insulated coating is sprayed or otherwise formed over a conductive metal such as copper, gold or aluminum.

Each of the bond wires 20 extends through the via 18 and includes a first end 20a bonded to one of the first electrical contacts 14 and a second end 20b bonded to one of the second electrical contacts 16. The via 18 preferably has dimensions sized to accommodate the plurality of bond wires 20. For example, the via 18 may have a diameter of about 200 um in order to accommodate from 6-10 of the bond wires 20. The size of the via 18 is calculated based on the pitch of the wire bond pads 16 and the wirebond capillary dimensions.

As shown in FIG. 1, the second electrical contacts 16 preferably are disposed directly below the via 18 and as will be explained in more detail below, are formed in the redistribution layer 30.

In one embodiment, a first encapsulation material 22 encapsulates the plurality of bond wires 20. The first encapsulation material 22 is preferably an epoxy, although other insulating materials may be used as well. It is preferred that the first encapsulation material 22 is disposed at least within the via 18. In FIG. 1, a portion of the first encapsulation material 22 is also disposed on and extends at least slightly beyond the first main surface 12a of the semiconductor substrate 12 since the bond wires 20 extend out of the via 18 and across the first main surface 12a. The encapsulating material 22 prevents unwanted movement of the bond wires 20. In one embodiment, the first encapsulation material 22 comprises epoxy.

Subsequent to the wire bonding and filling of the via 18 with the first encapsulation material 22, the support wafer is removed from the substrate 12.

The device 10 further preferably includes one, and preferably a plurality of external electrical contacts 24a and 24b for connection to other components. For example, a plurality of first external electrical contacts 24a are provided on the first main surface 12a of the semiconductor substrate 12 in FIG. 1 for connection to a semiconductor die 26. The first external electrical contacts 24a are preferably each in electrical communication with corresponding ones of the first electrical contacts 14. For example, conductive traces (not shown) can be used to connect the respective first and external electrical contacts 14, 24a. The semiconductor die 26 is preferably mounted proximate to the first main surface 12a of the semiconductor substrate 12 to facilitate electrical connection to the external electrical conductors 24a by way of, for example, solder balls 28 or the like.

The semiconductor die 26 is typically in the form of an integrated circuit (IC) or the like. The semiconductor die 26 may be made from any semiconductor material or combinations of materials, such as gallium arsenide, silicon germanium, silicon-on-insulator (SOI), silicon, monocrystalline silicon, the like, and combinations of the above. In FIG. 1, the semiconductor die 26 is mounted in a “flip-chip” configuration to the semiconductor substrate 12. However, other conventional mounting configurations can be used as well, such as wire bond.

Also in FIG. 1, a redistribution layer (RDL) 30 is formed on the second main surface 12b of the semiconductor substrate 12 and includes a plurality of the second external electrical connectors 24b in electrical communication with corresponding ones of the second electrical contacts 16. For example, the redistribution layer 30 may contain vias, traces, columns, or the like (not shown), as is conventionally known, for electrically connecting the respective second and external electrical connectors 16, 24b to one another. One or more other solder balls 32 may be bonded to respective ones of the external electrical connectors 24b in the redistribution layer 30, which enables attachment of the semiconductor device 10 to a printed circuit board (not shown) or a like device. In order, the substrate 12 is provided and contacts 14 and 24a are formed on the first surface 12a of the substrate 12. The substrate 12 may then be thinned such as by grinding the backside 12b. The redistribution layer 30 is formed on the second main surface 12b of the substrate 12 and then the vias 18 are formed, bond wires connected between the redistribution layer contacts 16 and first contacts 14, epoxy filling of via 18, then die 26 attach, molding and finally solder ball 32 attach.

In other embodiments, a redistribution layer (not shown) may also or alternatively be provided on the first main surface 12a of the semiconductor substrate 12.

It is noted that more than one via 18 may be utilized, as shown in FIG. 1, in order to accommodate all of the appropriate electrical connections.

After the vias 18 are formed, the bond wires 20 are threaded through the vias 18 (using conventional bonding wire apparatus) and the die 26 is attached to the first main surface 12a of the substrate 12, a second encapsulation material 34 may be formed over the die 26 and first main surface 12a of the substrate 12 using known techniques such as transfer molding. It also is noted the instead of two encapsulation materials 22 and 34 and two encapsulation steps, the vias 18 could be filled in the same step and with the same encapsulation material as when the die 26 and substrate first surface 12a are encapsulated.

There is shown in FIGS. 2-5 a preferred embodiment of a method for assembling a semiconductor device 10 in accordance with the invention. Referring to FIG. 2, the semiconductor substrate 12 is provided and the first electrical contacts 14 are formed on the first main surface 12a of the semiconductor substrate 12. The first external electrical contacts 24a also are formed on the first main surface 12a of the substrate 12 along with appropriate traces connecting the contacts 14 and the contacts 24a. The electrical contacts 14, 24a are preferably formed by an electroless nickel immersion gold (ENIG) process, electroless tin plating, or the like. However, other conventional methods may be used as well.

The redistribution layer 30 may also be formed as necessary at this stage. The redistribution layer 30 shown in FIG. 2 is formed on the second main surface 12b of the semiconductor substrate 12 and can be formed using conventional techniques, such as those disclosed in U.S. Pat. No. 8,669,140 assigned to Freescale Semiconductor, Inc., the entire contents of which are incorporated by reference herein. The redistribution layer 30 is formed to include any necessary external electrical connectors 24b.

Referring to FIG. 3, the vias 18 are formed through the semiconductor substrate 12 from the first main surface 12a to the second main surface 12b thereof. The vias 18 may be formed using conventional techniques, such as masking the first main surface 12a of the semiconductor substrate 12 and removing exposed portions of the semiconductor material by mechanical etching, chemical etching, or the like.

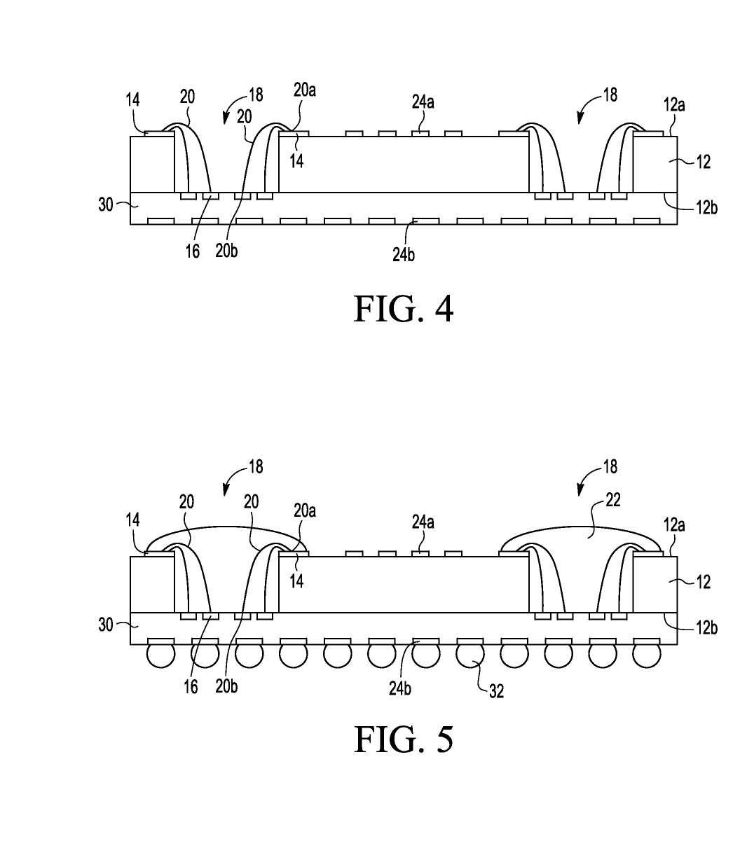

Referring to FIG. 4, the insulated bond wires 20 are bonded to corresponding ones of the first and second electrical contacts 14, 16. A wire bonding machine (not shown) may be used to bond the second end 20b of a bond wire 20 to a second electrical connector 16. The wire bonding machine may then run the bond wire 20 through the via 18 and subsequently bond the first end 20a of the bond wire 20 to a first electrical connector 14 on the first main surface 12a of the semiconductor substrate 12. The substrate 12 and redistribution layer 30 are attached to a temporary support wafer (not shown) to provide necessary support for the wirebonding process. The support wafer is removed after the wirebonding and filling the hole with epoxy material.

Referring to FIG. 5, the via 18 is filled with the encapsulating material 22, preferably an epoxy. In the embodiment shown in FIG. 5, the redistribution layer 30 serves as a boundary and the encapsulating material 22 may be filled into the via 18 through the opening at the first main surface 12a of the semiconductor substrate 12. The encapsulating material 22 is further allowed to overflow from the via 18 to cover the portions of the bond wires 20 located outside of the via 18. If necessary, the encapsulating material 22 may be cured.

In addition, other solder balls 32 may be bonded to the appropriate second or external electrical connectors 16, 24b using conventional methods. The solder balls 32 may be attached before or after the encapsulating materials 22 and 34 are applied. The solder balls 32 may also be attached earlier or later in the process, as desired.

The semiconductor die 26 may be attached to the structure shown in FIG. 5 using conventional techniques to arrive at the device 10 shown in FIG. 1.

In the foregoing specification, the invention has been described with reference to specific examples of embodiments of the invention. It will, however, be evident that various modifications and changes may be made therein without departing from the broader spirit and scope of the invention as set forth in the appended claims.

Those skilled in the art will recognize that boundaries between the above-described operations are merely illustrative. The multiple operations may be combined into a single operation, a single operation may be distributed in additional operations and operations may be executed at least partially overlapping in time. Further, alternative embodiments may include multiple instances of a particular operation, and with the exception of expressly ordered steps, the order of operations may be altered in various other embodiments.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

In the claims, the word ‘comprising’ or ‘having’ does not exclude the presence of other elements or steps then those listed in a claim. Further, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A semiconductor device, comprising:
a semiconductor substrate having opposing first and second main surfaces;
a via extending from the first main surface of the semiconductor substrate to the second main surface of the semiconductor substrate;
a plurality of first electrical connectors formed proximate the first main surface of the semiconductor substrate;
at least one redistribution layer having a first surface attached to the second main surface of the semiconductor substrate, and a plurality of second electrical connectors formed on the first surface of the redistribution layer and exposed in the via; and
a plurality of insulated bond wires, each extending through the via and having a first end bonded to a respective one of the plurality of first electrical connectors and a second end bonded to a respective one of the plurality of second electrical connectors.

2. The device of claim 1, further comprising at least one third electrical connector formed on the first main surface of the semiconductor substrate and in electrical communication with at least one of the plurality of first electrical connectors.

3. The device of claim 2, further comprising a semiconductor die mounted on the first main surface of the semiconductor substrate and electrically connected to the at least one third electrical connector.

4. The device of claim 1, wherein the at least one redistribution layer includes one or more third electrical connectors each in electrical communication with a respective one of the plurality of second electrical connectors.

5. The device of claim 4, further comprising one or more solder balls, each of which is bonded to a respective one of the one or more third electrical connectors.

6. The device of claim 1, further comprising a plurality of solder balls, each of which is bonded to a respective one of the plurality of second electrical connectors.

7. The device of claim 1, further comprising an encapsulating material disposed within the via and encapsulating the plurality of insulated bond wires, wherein a portion of the encapsulation material is disposed on the first main surface of the semiconductor substrate.

8. The device of claim 7, wherein the encapsulation material is an epoxy.

9. A method of forming a semiconductor device, the method comprising:
providing a semiconductor substrate having opposing first and second main surfaces;
forming a plurality of first electrical connectors on the first main surface of the semiconductor substrate;
forming a via extending from the first main surface of the semiconductor substrate to the second main surface of the semiconductor substrate;
forming at least one redistribution layer having a first surface and an opposite second surface;
forming a plurality of second electrical connectors on the first surface of the redistribution layer;
attaching the first surface of the redistribution layer to the second main surface of the semiconductor substrate, wherein the plurality of second electrical connectors are exposed in the via;
wire bonding a first end of each of a plurality of insulated bond wires to a respective one of the plurality of first electrical connectors and a second end of each of the plurality of insulated bond wires to a respective one of the plurality of second electrical connectors such that each of the plurality of bond wires extends through the via; and
encapsulating the plurality of bond wires in an encapsulating material, the encapsulating material being disposed at least within the via.

10. The method of claim 9, further comprising forming at least one third electrical connector on the first main surface of the semiconductor substrate and in electrical communication with at least one of the plurality of first electrical connectors.

11. The method of claim 10, further comprising electrically connecting a semiconductor die to the at least one third electrical connector and mounting the semiconductor die proximate the first main surface of the semiconductor substrate.

12. The method of claim 9, wherein the redistribution layer includes one or more third electrical connectors each in electrical communication with a respective one of the plurality of second electrical connectors.

13. The method of claim 12, further comprising bonding each of one or more solder balls to respective ones of the one or more third electrical connectors.

14. The method of claim 9, further comprising bonding each of a plurality of solder balls to respective ones of the plurality of second electrical connectors.

15. The method of claim 9, wherein a portion of the encapsulation material is disposed on the first main surface of the semiconductor substrate.

16. The method of claim 9, wherein the encapsulation material is an epoxy.

17. A semiconductor device, comprising:
a semiconductor substrate having opposing first and second main surfaces;
a via extending from the first main surface of the semiconductor substrate to the second main surface of the semiconductor substrate;
a plurality of first electrical contacts formed near the first main surface of the semiconductor substrate;
a redistribution layer having a first surface attached to the second main surface of the semiconductor substrate;
a plurality of second electrical contacts formed on the first surface of the redistribution layer and exposed in the via;
a plurality of insulated bond wires, each extending through the via and having a first end bonded to a respective one of the plurality of first electrical connectors and a second end bonded to a respective one of the plurality of second electrical connectors;
a plurality of third electrical contacts formed on the first main surface of the semiconductor substrate and in electrical communication with selected ones of the plurality of first electrical contacts; and
a semiconductor die mounted on the first main surface of the semiconductor substrate and electrically connected to the plurality of third electrical contacts.

18. The semiconductor device of claim 17, wherein the die is electrically connected to the third electrical contacts with first solder balls.

19. The semiconductor device of claim 17, further comprising:
wherein a plurality of fourth electrical contacts are formed in a second surface of the redistribution layer opposite the first surface, wherein the second and fourth electrical contacts are electrically connected with each other; and
a plurality of second solder balls, each of which is bonded to a respective one the fourth electrical contacts of the redistribution layer.

20. The semiconductor device of claim 19, further comprising an encapsulation material that fills the via and covers the insulated bond wires.
